(19) United States
(12) Patent Application Publication
(10) Pub. No.: US 2011/0049610 A1
(43) Pub. Date: Mar. 3, 2011

(54) NONVOLATILE MEMORY DEVICE AND METHOD OF FORMING THE SAME

(75) Inventors: Junkyu Yang, Seoul (KR); Jaeyoung Ahn, Seongnam-si (KR); Young-Geun Park, Suwon-si (KR); Kihyun Hwang, Seongnam-si (KR); Dongwoon Shin, Seongnam-si (KR); Juyul Lee, Seoul (KR)

(73) Assignee: SAMSUNG ELECTRONICS CO., LTD., Gyeonggi-do (KR)

(21) Appl. No.: 12/845,375

(22) Filed: Jul. 28, 2010

(30) Foreign Application Priority Data
Aug. 25, 2009 (KR) 10-2009-0078906

(51) Int. Cl. H01L 29/792

(52) U.S. Cl. 257/324; 257/E29.309

(57) ABSTRACT

Provided are a nonvolatile memory device and a method of forming the same. The nonvolatile memory device includes: a semiconductor substrate including a device isolation layer defining an active region; a tunnel insulating layer on the active region; a charge trapping layer on the tunnel insulating layer; a blocking insulating layer on the charge trapping layer and the device isolation layer; a gate electrode on the blocking insulating layer; and a barrier capping layer formed between the device isolation layer and the blocking insulating layer.

### CROSS-REFERENCE TO RELATED APPLICATIONS

This U.S. nonprovisional patent application claims priority under 35 U.S.C. §119 of Korean Patent Application 10-2009-0078906, filed in the Korean Intellectual Property Office on Aug. 25, 2009, the entire contents of which are hereby incorporated by reference.

### BACKGROUND

The present invention relates to a semiconductor memory device and a method of forming the same, and more particularly, to a nonvolatile memory device and a method of forming the same.

Generally, semiconductor memory devices can be classified as volatile memory devices or nonvolatile memory devices. The volatile memory device loses its stored information when the power source is interrupted, but the nonvolatile memory device can retain its stored information even though the power source is cut off. An example of a nonvolatile memory device is a flash memory device. The flash memory device is a highly integrated device developed by combining merits of EPROM (Erasable Programmable Read Only Memory) capable of programming and erasing and EEPROM (Electrically Erasable Programmable Read Only Memory) capable of electrically programming and erasing.

The flash memory device has a sequentially stacked structure of floating gates for storing data and control gates for controlling the floating gates. Such a structure impedes scaling down of memory devices due to a vertical height of the floating gates. In order to effectively reduce the vertical height of the memory cell and at the same time to maintain retention characteristics for retaining stored data for a long time, a flash memory device using a charge trapping layer has been developed.

### SUMMARY

The present inventive concept provides a nonvolatile memory device and a method of forming the same having improved reliability operation characteristics.

According to one aspect, the inventive concept is directed to a nonvolatile memory device including: a semiconductor substrate including a device isolation layer defining an active region; a tunnel insulating layer on the active region; a charge trapping layer on the tunnel insulating layer; a blocking insulating layer on the charge trapping layer and the device isolation layer; a gate electrode on the blocking insulating layer; and a barrier capping layer formed between the device isolation layer and the blocking insulating layer.

In some embodiments, the barrier capping layer may cover the device isolation layer and the charge trapping layer.

In some embodiments, the barrier capping layer may comprise the same material as that of the charge trapping layer.

In some embodiments, the barrier capping layer may cover the device isolation layer, and the blocking insulating layer may come into contact with the charge trapping layer.

In some embodiments, the barrier capping layer may include a silicon oxynitride layer.

In some embodiments, the thickness of the barrier capping layer may be thinner than that of the charge trapping layer.

In some embodiments, the blocking insulating layer may include a barrier insulating layer on the barrier capping layer and a high-k layer on the barrier insulating layer, and the barrier insulating layer may comprise the same material of that of the device isolation layer.

According to another aspect, the inventive concept is directed to a method of forming a nonvolatile memory device, the method including: forming a tunnel insulating layer on a semiconductor substrate; forming a charge trapping layer on the tunnel insulating layer; forming a trench by etching the tunnel insulating layer, the charge trapping layer, and the semiconductor substrate and forming a device isolation layer to fill the trench; forming a barrier capping layer on the device isolation layer; forming a blocking insulating layer on the barrier capping layer; and forming a gate electrode on the blocking insulating layer.

In some embodiments, the barrier capping layer may be formed to cover the device isolation layer and the charge trapping layer and be formed of the same material as that of the charge trapping layer.

In some embodiments, the barrier capping layer may be formed by nitriding a part of the device isolation layer.

### BRIEF DESCRIPTION OF THE DRAWINGS

The foregoing and other features and advantages of the inventive concept will be apparent from the more particular description of preferred embodiments of the inventive concept, as illustrated in the accompanying drawings in which like reference characters refer to the same parts throughout the different views. The drawings are not necessarily to scale, emphasis instead being placed upon illustrating the principles of the inventive concept. In the drawings, the thickness of layers and regions are exaggerated for clarity.

FIG. 1 is a plan view illustrating a NAND flash memory device according to an embodiment of the inventive concept.

FIG. 2 is a sectional view taken along the line I-I′ of FIG. 1 illustrating a nonvolatile memory device according to an embodiment of the inventive concept.

FIG. 3 is a sectional view taken along the line II-II′ of FIG. 1 illustrating a nonvolatile memory device according to an embodiment of the inventive concept.

FIG. 4 is a sectional view taken along the line III-III′ of FIG. 1 illustrating a nonvolatile memory device according to an embodiment of the inventive concept.

FIG. 5 is a sectional view taken along the line I-I′ of FIG. 1 illustrating a nonvolatile flash memory device according to another embodiment of the inventive concept.

FIG. 6 is a sectional view taken along the line II-II′ of FIG. 1 illustrating a nonvolatile flash memory device according to another embodiment of the inventive concept.

FIG. 7 is a sectional view taken along the line III-III′ of FIG. 1 illustrating a nonvolatile flash memory device according to another embodiment of the inventive concept.

FIG. 8 is a graph illustrating an energy band diagram of the nonvolatile memory device according to the embodiments of the inventive concept. Specifically, FIG. 8 is the graph illustrating the energy band diagram of portion A in FIG. 2.

FIG. 9 is the graph illustrating an energy band diagram according to a comparative example.

FIG. 10 is a graph illustrating characteristics of an erasing operation according to the embodiment of the inventive concept and the comparative example.

FIGS. 11 and 12 are graphs illustrating a retention characteristic according to the embodiment of the inventive concept and the comparative example.

FIG. 13 is a graph illustrating characteristics of the erasing operation according to the embodiment of the inventive concept.

FIGS. 14A through 14D are diagrams illustrating a method of forming the nonvolatile memory device according to an embodiment of the inventive concept.

FIGS. 15A through 15D are diagrams illustrating a method of forming a nonvolatile memory device according to another embodiment of the inventive concept.

FIG. 16 is a block diagram illustrating an electronic system including the nonvolatile memory device according to embodiments of the inventive concept.

FIG. 17 is a block diagram illustrating a memory card including the nonvolatile memory device according to an embodiment of the inventive concept.

### DETAILED DESCRIPTION OF EMBODIMENTS

Preferred embodiments of the present inventive concept will be described below in more detail with reference to the accompanying drawings. The present inventive concept may, however, be embodied in different forms and should not be constructed as limited to the embodiments set forth herein.

It will be understood that, although the terms “first”, “second”, and so on may be used herein to describe each of the components, these components should not be limited by these terms. These terms are only used to distinguish one component from another component.

In the drawings, each of the components may have been exaggerated for clarity. Like reference numerals refer to like components throughout the specification.

Some embodiments to which the scope of the inventive concept can be applied are illustratively described below, but others modified embodiments will not be described for brevity. However, it will be apparent to those skilled in the art that various modification and changes may be made thereto without departing from the scope and spirit of the inventive concept based on the above description and following embodiments.

A NAND flash memory device is described below as an embodiment of the invention concept, but the inventive concept is applicable to various types of memory devices (for example, NOR flash).

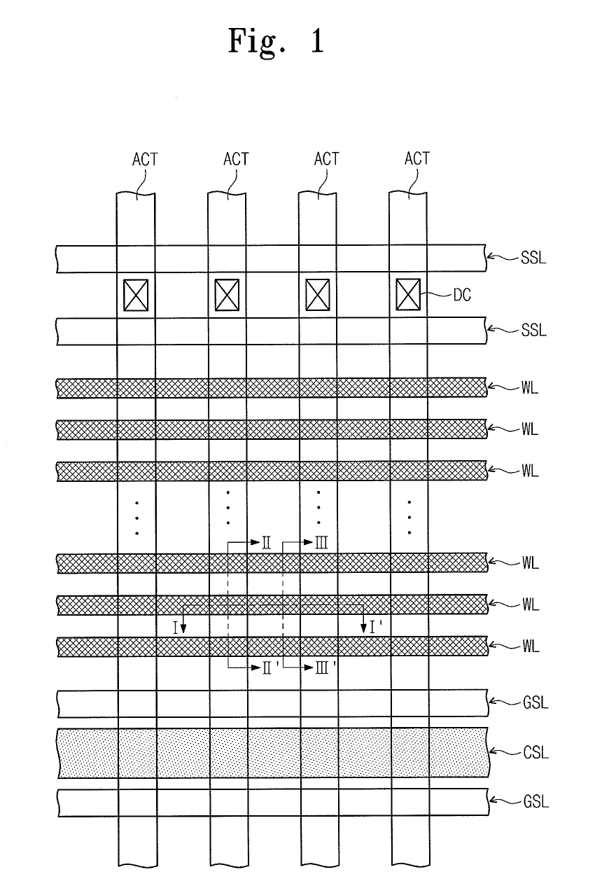

FIG. 1 is a plan view illustrating a NAND flash memory device according to an embodiment of the inventive concept.

Referring to FIG. 1, active regions ACT are arranged in parallel in one direction on a semiconductor substrate. Word lines WL are arranged to intersect the active regions ACT. Ground selection lines GSL are arranged on one side of the word lines WL. String selection lines SSL are arranged on the other side of the word lines WL. A common source line CSL is arranged between the ground selection lines GSL. Bit line contacts DC are formed between the string selection lines SSL. The gaps between the string selection lines SSL and the ground selection lines GSL may become narrower as the nonvolatile memory device is subjected to scaling-down. For this reason, the self-aligned common source line CSL may be provided between the ground selection lines GSL, and the self-aligned bit line contacts DC may be provided between the string selection lines SSL.

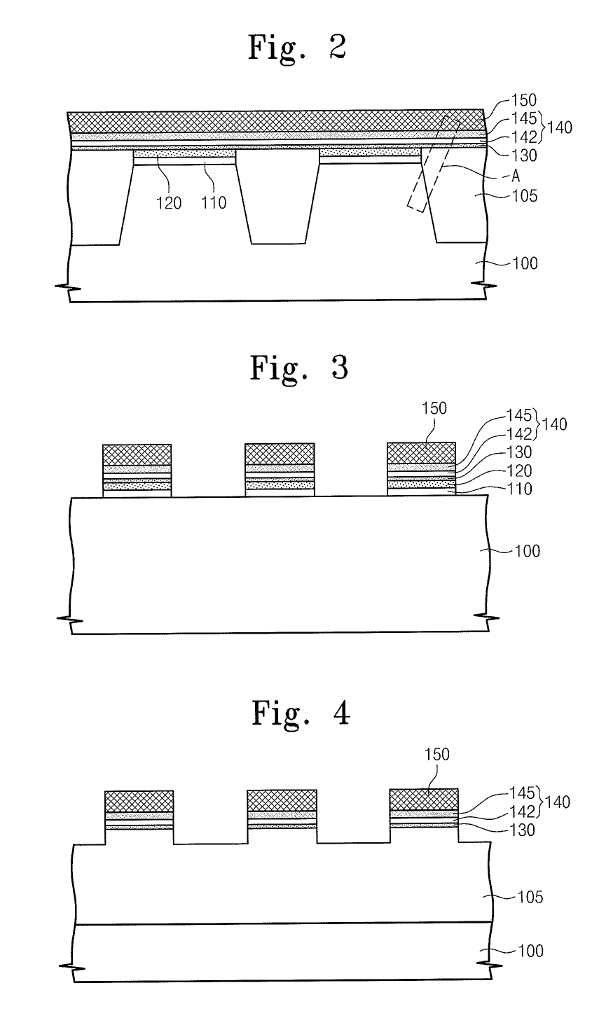

The nonvolatile memory device according to an embodiment of the inventive concept will be described with reference to FIGS. 2 through 4. FIG. 2 is a sectional view taken along the line I-I′ of FIG. 1, FIG. 3 is a sectional view taken along the line II-II′ of FIG. 1, and FIG. 4 is a sectional view taken along the line of FIG. 1.

A semiconductor substrate 100 includes device isolation layers 105 defining the active regions ACT (FIG. 1). A tunnel insulating layer 110 is formed on the semiconductor substrate 100 of the active regions. The tunnel insulating layer 110 may include at least one of a silicon oxide layer and a silicon oxide nitride layer. The silicon oxide layer forming the tunnel insulating layer 110 may have a thickness so as not to be directly subjected to tunneling.

A charge trapping layer 120 is formed on the tunnel insulating layer 110. The charge trapping layer 120 may be formed of one of silicon nitride, hafnium oxide, zirconium oxide (ZrO), tantalum oxide (TaO), hafnium silicon oxide (HfSiO), hafnium oxynitride (HfON), zirconium oxynitride (ZrON), hafnium silicon oxynitride (HfSiON), and hafnium aluminum oxynitride (HfAlON). According to an embodiment of the inventive concept, the charge trapping layer 120 may be formed of silicon nitride.

A blocking insulating layer 140 is formed on the charge trapping layer 120. The blocking insulating layer 140 may include a barrier insulating layer 142 on the charge trapping layer 120 and a high-k layer 145 on the barrier insulating layer 142. The high-k layer 145 may have a dielectric constant larger than that of the tunnel insulating layer 110. For example, the high-k layer 145 may comprise insulating metal oxide. Specifically, the high-k layer 145 may include at least one of an aluminum oxide layer, a lanthanum hafnium oxide layer (LaHfO), a lanthanum aluminum oxide layer (LaAlO), and a dysprosium scandium oxide layer (DyScO). According to an embodiment of the inventive concept, the high-k layer 145 may be formed of aluminum oxide.

The electron affinity of the barrier insulating layer 142 may be smaller than that of the high-k layer 145. Here, the electron affinity is the amount of energy required to move from the vacuum level to the lower edge of the conduction band. Since the barrier insulating layer 142 has a small electron affinity, charges may be prevented from being released to a gate electrode and thus a retention characteristic may be improved. The barrier insulating layer 142 may be formed of a silicon oxide such as a middle temperature oxide.

A gate electrode 150 is formed on the blocking insulating layer 140. The gate electrode 150 comprises a conductive material a work function of which is 4 eV or more. A tunneling probability of the charges, which moves from the gate electrode 150 to the charge trapping layer 120 via the blocking insulating layer 140, is in inversion proportional to the work function of the gate electrode 150. The gate electrode 150 may be formed of a conductive layer a work function of which is larger than 4.0 eV. Therefore, it is possible to lower the tunneling probability of the charges moving via the blocking insulating layer 140. The gate electrode 150 may be formed of a conductive material a work function of which is larger than 4.0 eV, such as metal or doped silicon. According to an embodiment of the inventive concept, the gate electrode 150 may be formed of a tungsten nitride on the blocking insulating layer 140 and tungsten on the tungsten nitride.

As illustrated in FIG. 1, the tunnel insulating layer 110, the charge trapping layer 120, a barrier capping layer 130, the blocking insulating layer 140, and the gate electrode 150 form the work lines WL. Referring to FIG. 3, a reverse region may be formed by the fringing field of the gate electrode 150, even when a source/drain region is not disposed in the active region between the word lines WL. In this case, the word lines WL may be disposed sufficiently close to each other so that the reverse region is formed by the fringing field. Alternatively, unlike the embodiment of the inventive concept, the source/drain region may be disposed in the active region between the word lines WL.

Referring to FIG. 4, the height of the upper surface of the device isolation layer 105 which is crossed by the gate electrode 150 may be higher than the height of the upper surface of the device isolation layer 105 which is not crossed by the gate electrode 150. With such a configuration, since the charge trapping layer 120 is not connected to the adjacent charge trapping layer 120, the charges trapped in the charge trapping layer 120 may be prevented from being lost or spreading in any direction.

The barrier capping layer 130 is disposed between the device isolation layer 105 and the blocking insulating layer 140. The barrier capping layer 130 may cover the device isolation layer 105 and the charge trapping layer 120. The barrier capping layer 130 may comprise the same material as that of the charge trapping layer 120. For example, the barrier capping layer 130 may be a silicon nitride layer. The thickness of the barrier capping layer 130 may be thinner than that of the charge trapping layer 120.

The barrier capping layer 130 may prevent the metal material of the blocking insulating layer 140 and the gate electrode 150 from spreading to the device isolation layer 105. When the metal material is spread to the device isolation layer 105, a charge loss path may occur in the upper portion of the device isolation layer 105. Then, the charges trapped in the charge trapping layer 120 may be lost to the device isolation layer 105. Accordingly, the barrier capping layer 130 may serve to minimize such a charge loss path.

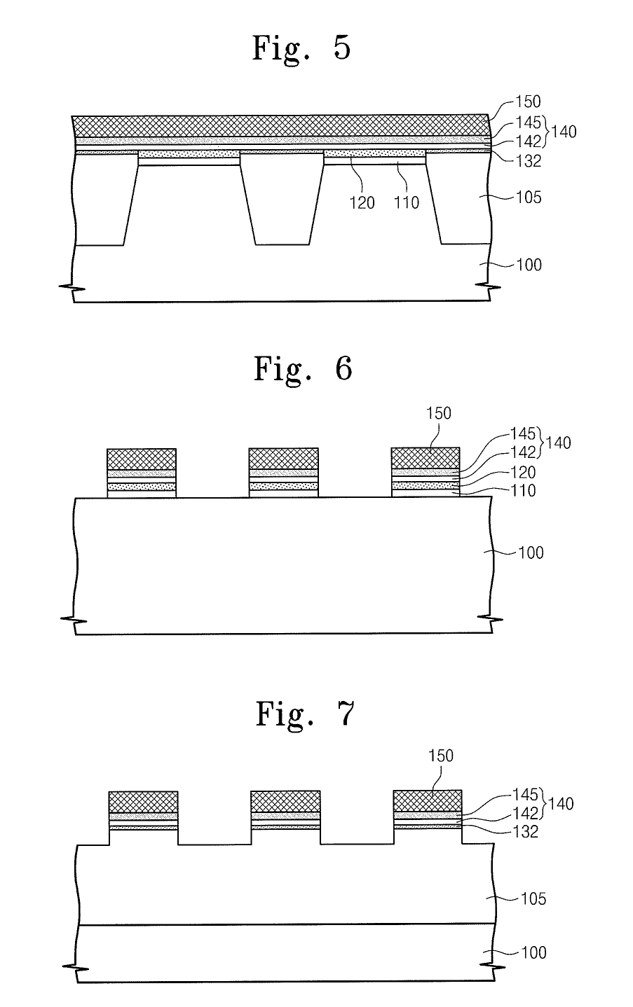

Referring to FIGS. 5 through 7, a nonvolatile memory element according to another embodiment of the inventive concept will be described. FIG. 5 is a sectional view taken along the line I-I′ of FIG. 1, FIG. 6 is a sectional view taken along the line II-II′ of FIG. 1, and FIG. 7 is a sectional view taken along the line of FIG. 1.

A semiconductor substrate 100 includes device isolation layers 105 defining an active region ACT (FIG. 1). A tunnel insulating layer 110 is disposed on the semiconductor substrate 100 of the active region. The tunnel insulating layer 110 may include at least one of a silicon oxide film and a silicon oxynitride layer. The silicon oxide film inclined in the tunnel insulating layer 110 may have an adequate thickness so that no direct tunneling occurs.

A charge trapping layer 120 is formed on the tunnel insulating layer 110. The charge trapping layer 120 may be formed of one of silicon nitride, hafnium oxide, zirconium oxide (ZrO), tantalum oxide (TaO), hafnium silicon oxide (HfSiO), hafnium oxynitride (HfON), zirconium oxynitride (ZrON), hafnium silicon oxynitride (HfSiON), and hafnium aluminum oxynitride (HfAlON). According to an embodiment of the inventive concept, the charge trapping layer 120 may be a silicon nitride.

A blocking insulating layer 140 is formed on the charge trapping layer 120. The blocking insulating layer 140 may includes a barrier insulating layer 142 on the charge trapping layer 120 and a high-k layer 145 on the barrier insulating layer 142. The high-k layer 145 may have a dielectric constant larger than that of the tunnel insulating layer 110. For example, the high-k layer 145 may comprise insulating metal oxide. Specifically, the high-k layer 145 may include at least one of an aluminum oxide film, a lanthanum hafnium oxide layer (LaHfO), a lanthanum aluminum oxide layer (LaAlO), and a dysprosium scandium oxide layer (DyScO). According to an embodiment of the inventive concept, the high-k layer 145 may be an aluminum oxide layer.

The electron affinity of the barrier insulating layer 142 may be smaller than that of the high-k layer 145. Here, the electron affinity is the amount of energy required to move from the vacuum level to the lower edge of the conduction band. The barrier insulating layer 142 has a small electron affinity. Therefore, since charges may be prevented from being released to a gate electrode, it is possible to improve a retention characteristic. The barrier insulating layer 142 may be a silicon oxide layer such as a middle temperature oxide layer.

A gate electrode 150 is formed on the blocking insulating layer 140. The gate electrode 150 comprises a conductive material a work function of which is 4 eV or more. A tunneling probability of the charges, which moves from the gate electrode 150 to the charge trapping layer 120 via the blocking insulating layer 140, is in inversion proportional to the work function of the gate electrode 150. The gate electrode 150 may be formed of a conductive layer a work function of which is larger than 4.0 eV. Therefore, it is possible to reduce the tunneling probability of the charges moving via the blocking insulating layer 140. The gate electrode 150 may be formed of a conductive material such as metal or doped silicon a work function of which is larger than 4.0 eV. According to an embodiment of the inventive concept, the gate electrode 150 may be formed of a tungsten nitride on the blocking insulating layer 140 and tungsten on the tungsten nitride.

As illustrated in FIG. 1, the tunnel insulating layer 110, the charge trapping layer 120, a barrier capping layer 130, the blocking insulating layer 140, and the gate electrode 150 form the work lines WL. Referring to FIG. 6, a reverse region may be formed by a fringing field of the gate electrode 150, even when a source/drain region is not disposed in the active region between the word lines WL. In this case, the word lines WL may be disposed sufficiently close to each other so that the reverse region is formed by the fringing field. Alternatively, unlike the embodiment of the inventive concept, the source/drain region may be disposed in the active region between the word lines WL.

Referring to FIG. 7, the height of the upper surface of the device isolation layer 105 which is crossed by the gate electrode 150 may be higher than the height of the upper surface of the device isolation layer 105 which is not crossed by the gate electrode 150. With such a configuration, since the charge trapping layer 120 is not connected to the adjacent charge trapping layer 120, the charges trapped in the charge trapping layer 120 may be prevented from being lost or spreading in any direction.

A barrier capping layer 132 is formed between the device isolation layer 105 and the blocking insulating layer 140. The barrier capping layer 132 may cover the device isolation layer 105 and the blocking insulating layer 140 may come into contact with the charge trapping layer 120. The barrier capping layer 132 may not cover the charge trapping layer 120. The thickness of the barrier capping layer 132 may be thinner than the thickness of the charge trapping layer 120. The barrier capping layer 132 may comprise a material containing a charge trapping site. For example, the barrier capping layer 132 may be a silicon nitride layer.

The barrier capping layer 132 may prevent the metal material of the blocking insulating layer 140 and the gate electrode 150 from spreading to the device isolation layer 105. When the metal material is spread to the device isolation layer 105, a charge loss path may occur in the upper portion of the device isolation layer 105. Then, the charges trapped in the charge trapping layer 120 may be lost to the device isolation layer 105. Accordingly, the barrier capping layer 132 may serve as minimizing such a charge loss path.

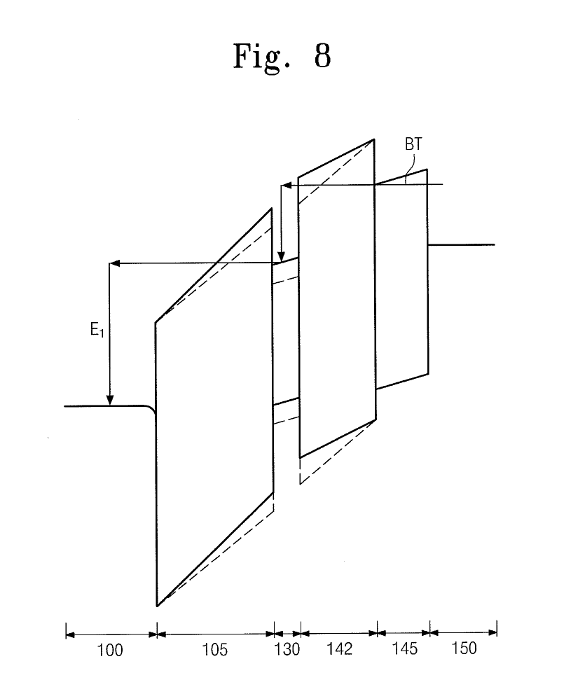

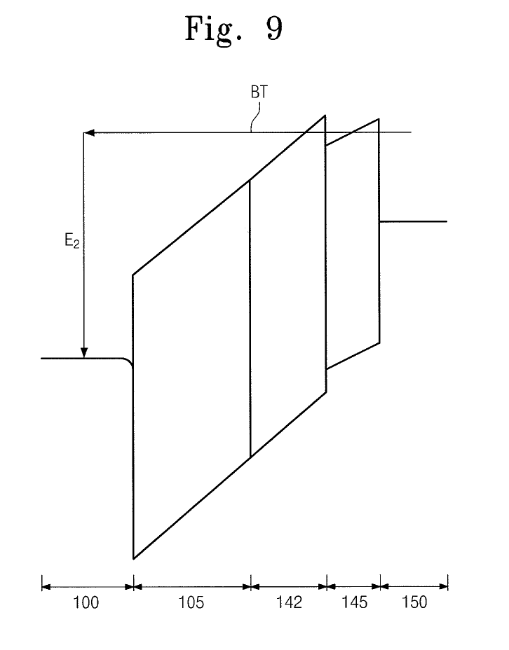

FIG. 8 is a graph illustrating an energy band diagram of the nonvolatile memory device according to the embodiments of the inventive concept. FIG. 8 is the graph illustrating the energy band diagram of portion “A” in FIG. 2. FIG. 9 is the graph illustrating an energy band diagram according to a comparative example.

Referring to FIGS. 2 and 8, the nonvolatile memory device according to the embodiments of the inventive concepts includes the device isolation layer 105 formed on the semiconductor substrate 100, the barrier capping layer 130 on the device isolation layer 105, the barrier insulating layer 142 on the barrier capping layer 130, the high-k layer 145 on the barrier insulating layer 142, and the gate electrode 150 on the high-k layer 145.

The energy band diagram illustrated in FIG. 8 indicates that the nonvolatile memory device is in an erased state. When an erasing voltage is applied to the gate electrode 150, a back-tunneling (BT) phenomenon, that is, an electron tunneling from the gate electrode 150 to the semiconductor substrate 100 may occur. During the back tunneling, the barrier capping layer 130 on the device isolation layer 105 may trap some of the back tunneling charges. When the barrier capping layer 130 traps the charges, the electron potential is increased and thus the energy band is raised. A solid line in FIG. 8 indicates a state where the charges are trapped by the barrier capping layer 130 and a dashed line indicates a state where no charge is trapped.

When the barrier capping layer 130 traps the charges, the back-tunneling electrons may move relatively longer. This is because the electron affinity of the barrier capping layer 130 is larger than that of the barrier insulating layer 142 and the device isolation layer 105. The thickness of the barrier insulating layer 142 and the device isolation layer 105 in which the back-tunneling of electrons occurs may become thicker. Accordingly, the back-tunneling may be reduced in the erasing operation and a variation (ΔVth) in a threshold voltage may readily be increased after the erasing operation.

On the other hand, an electric field applied to the edge of the active region by the back-tunneling may be lessened. It can be verified that an electric field E1 illustrated in FIG. 8 is weaker than an electric field E2 illustrated in FIG. 9. This lessening of electric field may inhibit the electric field from concentrating during a program and erasing operation. Accordingly, since the edge of the active region does not deteriorate and the trapped charges are not lost, it is possible to improve the reliability of the nonvolatile memory device according to the embodiment.

Referring to FIG. 9, no barrier capping layer is formed, unlike FIG. 8. When no barrier capping layer is formed, the distance of the back-tunneling BT of the electrons may be relatively shorter. Moreover, the thickness of the barrier insulating layer 142 in which the back-tunneling of electrons occurs may become thinner. Therefore, when no barrier capping layer is formed, the back-tunneling is increased and thus the variation in the threshold voltage may be decreased after the easing operation.

On the other hand, since the electric field E2 applied to the edge of the active region is relatively larger than that according to the embodiment of the inventive concept. Therefore, when the edge of the active region deteriorates, the trapped charges may be lost.

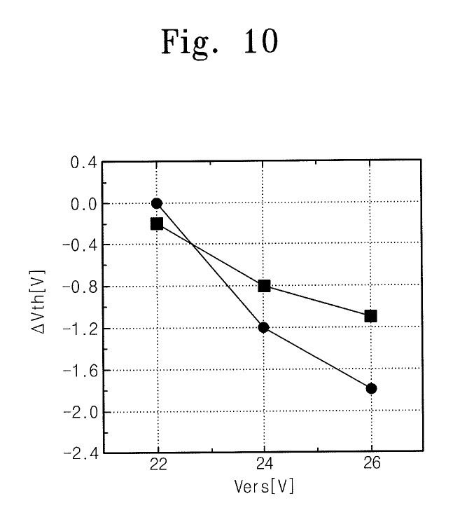

FIG. 10 is a graph illustrating the characteristics of the erasing operations according to the embodiment of the inventive concept and the comparative example. In FIG. 10, the horizontal axis represents an erasing voltage (Vers) and the vertical axis represents a variation value (ΔVth) of the threshold voltage. The embodiment of the inventive concept is indicated by -- and the comparative example is indicated by -▪-.

Referring to FIG. 10, according to the embodiment of the inventive concept, the barrier capping layer is formed, as illustrated in the energy band diagram in FIG. 8. According to the comparative example, no barrier capping layer is formed, as illustrated in FIG. 9. In the embodiment of the inventive concept, the variation in the threshold voltage is larger. It may be considered that this is caused due to a decrease in the back-tunneling by the barrier capping layer during the erasing operation.

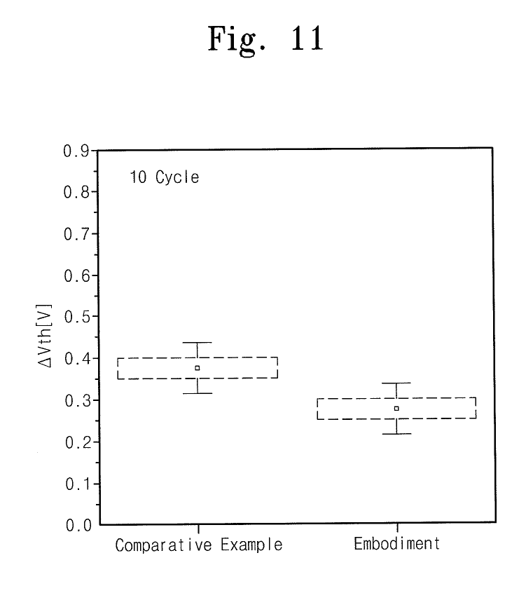

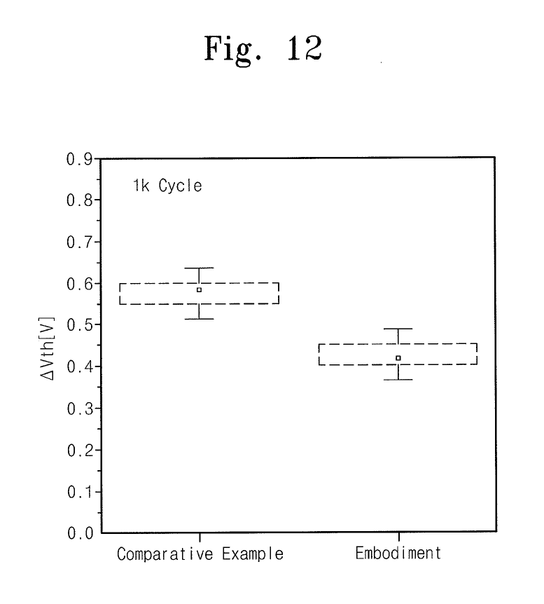

FIGS. 11 and 12 are graphs illustrating a retention characteristic according to the embodiment and the comparative example of the inventive concept. The vertical axis represents the variation value (ΔVth) of the threshold voltage. In the embodiment of the inventive concept, the barrier capping layer is formed, as illustrated in FIG. 8. In the comparative example, no barrier capping layer is formed, as illustrated in FIG. 9. The lower lines and upper lines of box plots illustrated FIGS. 11 and 12 indicate data corresponding to 5% and data corresponding to 95%, respectively. Dot boxes indicate data corresponding to 25% to 75% and the rectangles illustrated in the dot boxes indicate an average value.

Referring to FIGS. 11 and 12, the retention characteristic is measured using a parameter called HTS (High Temperature Stress). Here, the HTS refers to a parameter for the retention characteristic for measuring the variation (ΔVth) of the threshold voltage after baking a device at about 200° C. The variation in the threshold voltage in FIG. 11 is measured after the program and erasing operation is repeated 10 times and the device is baked. The variation in the threshold voltage in FIG. 12 is measured after the program erasing operation is repeated 1000 times and the device is baked. The variation value of the threshold voltage is smaller in the embodiment of the inventive concept. This is because the charge loss path is prevented from occurring in the upper portion of the device isolation layer by the barrier capping layer and the electric field applied to the edge of the active region is lessened. In the embodiment of the inventive concept, accordingly, the charge loss is reduced and the variation value of the threshold voltage is small, thereby improving the retention characteristic.

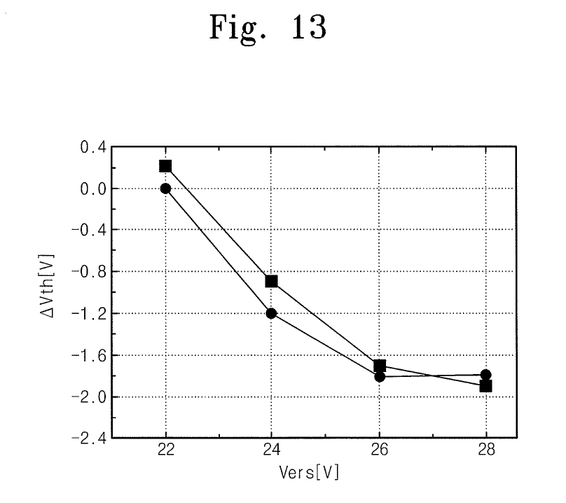

FIG. 13 is a graph illustrating the characteristics of the erasing operation according to the embodiment of the inventive concept. In FIG. 13, the horizontal axis represents an erasing voltage (Vers) and the vertical axis represents a variation value (ΔVth) of the threshold voltage. In the configuration according to the embodiment of the inventive concept, a case where the blocking insulating layer is formed and the subsequent process is performed is indicated by --, whereas a case where the subsequent process is not performed is indicated by -▪-. Here, examples of the subsequent process include a wet oxidation process, a dry oxidation process, and a heat treatment process in a nitrogen or ammonia ambience.

Referring to FIG. 13, the substantially same variation in the threshold voltage is obtained in the case where the subsequent process is performed and the case where the subsequent process is not performed. This is because the barrier capping layer according to the embodiment of the inventive concept serves as a barrier in the case where the subsequent process is performed. That is, the barrier capping layer can prevent the material of the blocking insulating layer or the gate electrode from spreading the upper portion of the device isolation layer. Moreover, the barrier capping layer can prevent the tunnel insulating layer and the charge trapping layer from being deformed.

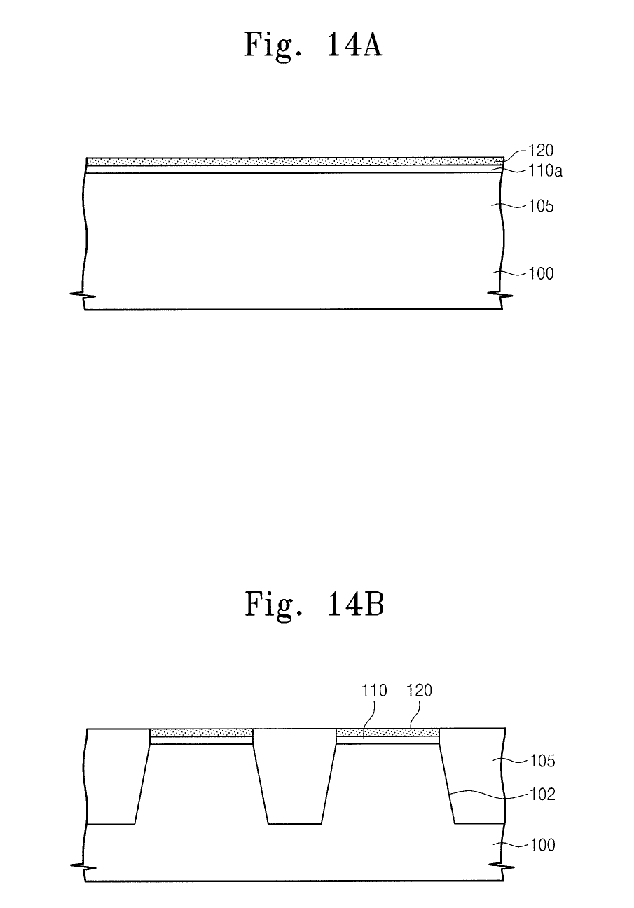

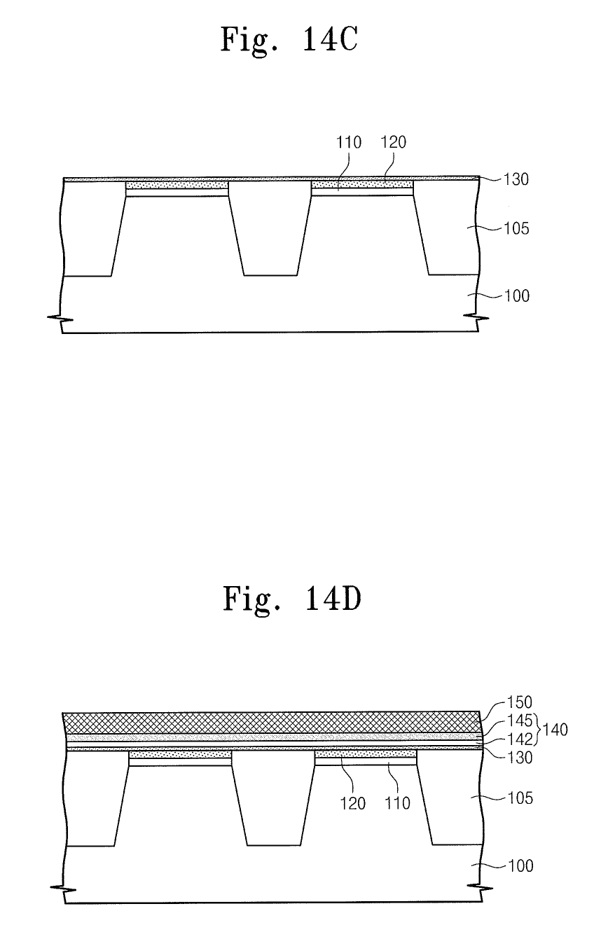

FIGS. 14A through 14D are diagrams illustrating a method of forming the nonvolatile memory device according to an embodiment of the inventive concept.

Referring to FIG. 14A, a preliminary tunnel insulating layer 110a is formed on the semiconductor substrate 100. The preliminary tunnel insulating layer 110a may be formed by a thermal oxidation process. The preliminary tunnel insulating layer 110a may be one of a silicon oxide layer and a silicon oxynitride layer. For example, the preliminary tunnel insulating layer 110a may be formed of a silicon oxide by the thermal oxidation process.

A preliminary charge trapping layer 120a is formed on the preliminary tunnel insulating layer 110a. The preliminary charge trapping layer 120a may be formed of one of silicon nitride, hafnium oxide, zirconium oxide (ZrO), tantalum oxide (TaO), hafnium silicon oxide (HfSiO), hafnium oxynitride (HfON), zirconium oxynitride (ZrON), hafnium silicon oxynitride (HfSiON), and hafnium aluminum oxynitride (HfAlON). According to an embodiment of the inventive concept, the preliminary charge trapping layer 120a may be formed of silicon nitride.

Referring to FIG. 14B, the preliminary charge trapping layer 120a, the preliminary tunnel insulating layer 110a, and the semiconductor substrate 100 are etched to form trenches 102. The device isolation layers 105 are formed to fill the trenches 102. The device isolation layers 105 may be formed by a shallow trench isolation process. The device isolation layers 105 may be formed of a silicon oxide.

While the device isolation layers 105 are formed, the preliminary charge trapping layer 120a and the preliminary tunnel insulating layer 110a are patterned to form the charge trapping layer 120 and the tunnel insulating layer 110. Accordingly, the charge trapping layer 120 may be self-aligned in the device isolation layer 105. The charge trapping layer 120 may be termed a self-aligned trap layer.

Referring to FIG. 14C, the barrier capping layer 130 is formed to cover the charge trapping layer 120 and the device isolation layer 105. The barrier capping layer 130 may be formed of the same material as that of the charge trapping layer 120. For example, the barrier capping layer 130 may be formed of a silicon nitride. Alternatively, the barrier capping layer 130 may be formed of a silicon oxynitride. The barrier capping layer 130 may be formed by an atomic layer deposition or a low temperature-chemical vapor deposition.

The barrier capping layer 130 may be formed so as to have a thickness thinner than that of the charge trapping layer 120. The trap density of the barrier capping layer 130 is substantially the same as that of the charge trapping layer 120. The barrier capping layer 130 may be formed of a material of which an electron affinity is the same as or is similar to that of the charge trapping layer 120.

Referring to FIG. 14D, the blocking insulating layer 140 is formed on the barrier capping layer 130. The forming of the blocking insulating layer 140 may include forming the barrier insulating layer 142 on the barrier capping layer 130 and forming the high-k layer 145 on the barrier insulating layer 142. The high-k layer 145 may have the dielectric constant larger than that of the tunnel insulating layer 110. For example, the high-k layer 145 may be formed of insulating metal oxide. Specifically, the high-k layer 145 may be formed of one of an aluminum oxide, a lanthanum hafnium oxide (LaHfO), a lanthanum aluminum oxide (LaAlO), and a dysprosium scandium oxide (DyScO). According to an embodiment of the inventive concept, the high-k layer 145 may be formed of an aluminum oxide.

The electron affinity of the barrier insulating layer 142 may be smaller than that of the high-k layer 145. Since the barrier insulating layer 142 has the smaller electron affinity, the charges may be prevented from being released to a gate electrode and thus a retention characteristic may be improved. The barrier insulating layer 142 may be formed of a silicon oxide such as a middle temperature oxide.

A gate electrode 150 is formed on the blocking insulating layer 140. The gate electrode 150 may be formed of a conductive material a work function of which is 4eV or more. A tunneling probability of the charges, which moves from the gate electrode 150 to the charge trapping layer 120 via the blocking insulating layer 140, is in inversion proportional to the work function of the gate electrode 150. The gate electrode 150 may be formed of a conductive layer a work function of which is larger than 4.0 eV. Therefore, it is possible to lower the tunneling probability of the charges moving via the blocking insulating layer 140. The gate electrode 150 may be formed of a conductive material a work function of which is larger than 4.0 eV, such as metal or doped silicon. According to an embodiment of the inventive concept, the gate electrode 150 may be formed of a tungsten nitride on the blocking insulating layer 140 and tungsten on the tungsten nitride.

According to an embodiment of the inventive concept, the barrier capping layer 130 may prevent the material of the blocking insulating layer 140 and the gate electrode 150 from spreading to the upper portion of the device isolation layer 105. Accordingly, the barrier capping layer 130 may prevent a charge loss path from being formed in the upper portion of the device isolation layer 105. Since the barrier capping layer 130 according to an embodiment of the inventive concept covers the charge trapping layer 120, it is possible to prevent the charge trapping layer 120 and the tunnel insulating layer 110 from being deformed in the subsequent process after forming the charge trapping layer 120.

On the other hand, the barrier capping layer 130 may lessen an electric field applied to the edge of the active region, thereby improving the retention characteristic of the device. The barrier capping layer 130 decreases the back tunneling, thereby improving the reliability of the device.

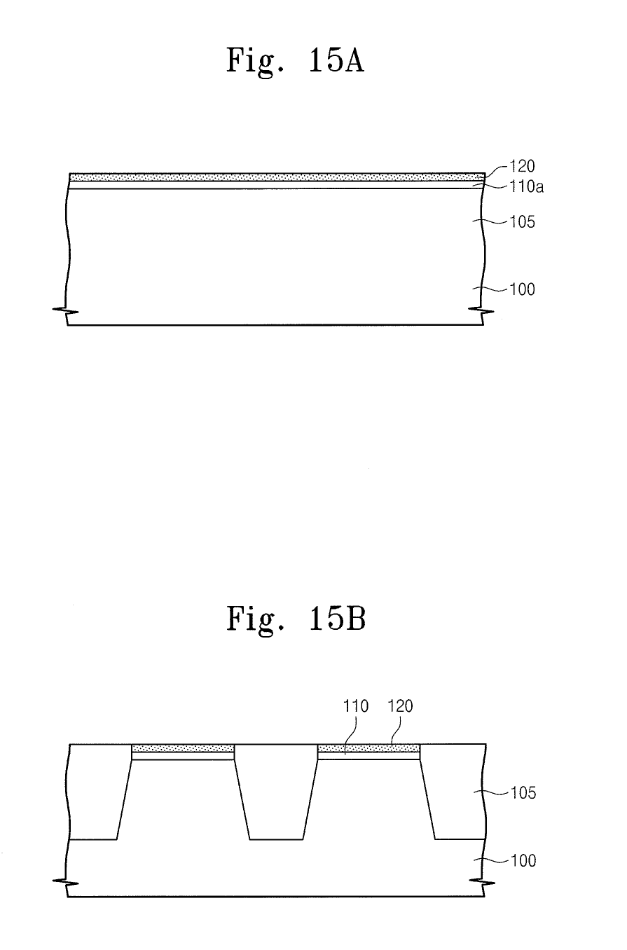

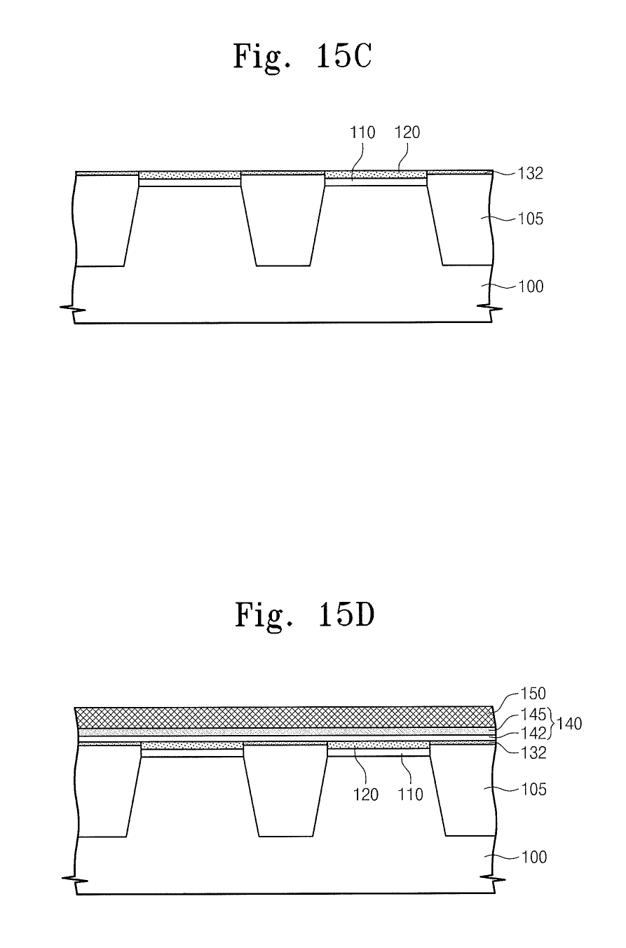

FIGS. 15A through 15D are diagrams illustrating a method of forming a nonvolatile memory device according to another embodiment of the inventive concept.

Referring to FIG. 15A, a preliminary tunnel insulating layer 110a is formed on the semiconductor substrate 100. The preliminary tunnel insulating layer 110a may be formed by a thermal oxidation process. The preliminary tunnel insulating layer 110a may be formed of one of silicon oxide and silicon oxynitride. For example, the preliminary tunnel insulating layer 110a may be formed of silicon oxide by the thermal oxidation process.

A preliminary charge trapping layer 120a is formed on the preliminary tunnel insulating layer 110a. The preliminary charge trapping layer 120a may be formed of one of silicon nitride, hafnium oxide, zirconium oxide (ZrO), tantalum oxide (TaO), hafnium silicon oxide (HfSiO), hafnium oxynitride (HfON), zirconium oxynitride (ZrON), hafnium silicon oxynitride (HfSiON), and hafnium aluminum oxynitride (HfAlON). According to an embodiment of the inventive concept, the preliminary charge trapping layer 120a may be formed of silicon nitride.

Referring to FIG. 15B, the preliminary charge trapping layer 120a, the preliminary tunnel insulating layer 110a, and the semiconductor substrate 100 are etched to form trenches 102. Preliminary device isolation layers 105a are formed to fill the trenches 102. The preliminary device isolation layers 105a may be formed by a shallow trench isolation process. The preliminary device isolation layers 105a may be formed of silicon oxide.

While the preliminary device isolation layers 105a are formed, the preliminary charge trapping layer 120a and the preliminary tunnel insulating layer 110a are patterned to form the charge trapping layer 120 and the tunnel insulating layer 110. Accordingly, the charge trapping layer 120 may be self-aligned in the preliminary device isolation layer 105a. The charge trapping layer 120 may be termed a self-aligned trap layer.

Referring to FIG. 15C, the upper portion of the preliminary device isolation layers 105a are changed to the barrier capping layer 132. In this way, the device isolation layers 105 are formed. The barrier capping layer 132 may be formed so as to have a thickness thinner than that of the charge trapping layer 120. The barrier capping layer 132 may be formed so as to have a charge trap site.

Specifically, the barrier capping layer 132 may be formed on the upper portions of the preliminary device isolation layers 105a by a nitridation process. The nitridation process may be a plasma nitridation process or a rapid thermal nitridation process. The nitridation process may be performed by injecting ammonia gas (NH3) or a nitrogen gas (N2). The barrier capping layer 132 may be formed of a silicon oxynitride.

Referring to FIG. 15D, the blocking insulating layer 140 is formed on the barrier capping layer 132 and the charge trapping layer 120. The forming of the blocking insulating layer 140 may include forming the barrier insulating layer 142 on the barrier capping layer 132 and the charge trapping layer 120 and forming the high-k layer 145 on the barrier insulating layer 142. The high-k layer 145 may have the dielectric constant larger than that of the tunnel insulating layer 110. For example, the high-k layer 145 may be formed of insulating metal oxide. Specifically, the high-k layer 145 may be formed of one of aluminum oxide, lanthanum hafnium oxide (LaHfO), lanthanum aluminum oxide (LaAlO), and dysprosium scandium oxide (DyScO). According to an embodiment of the inventive concept, the high-k layer 145 may be formed of aluminum oxide.

The electron affinity of the barrier insulating layer 142 may be smaller than that of the high-k layer 145. Since the barrier insulating layer 142 has the smaller electron affinity, the charges may be prevented from being released to a gate electrode and thus a retention characteristic may be improved. The barrier insulating layer 142 may be formed of a silicon oxide such as a middle temperature oxide.

A gate electrode 150 is formed on the blocking insulating layer 140. The gate electrode 150 may be formed of a conductive material a work function of which is 4 eV or more. A tunneling probability of the charges, which moves from the gate electrode 150 to the charge trapping layer 120 via the blocking insulating layer 140, is in inversion proportional to the work function of the gate electrode 150. The gate electrode 150 may be formed of a conductive layer a work function of which is larger than 4.0 eV. Therefore, it is possible to lower the tunneling probability of the charges moving via the blocking insulating layer 140. The gate electrode 150 may be formed of a conductive material of which a work function is larger than 4.0 eV, such as metal or doped silicon. According to an embodiment of the inventive concept, the gate electrode 150 may be formed of tungsten nitride on the blocking insulating layer 140 and tungsten on tungsten nitride.

According to an embodiment of the inventive concept, the barrier capping layer 130 may prevent the material of the blocking insulating layer 140 and the gate electrode 150 from spreading to the upper portion of the device isolation layer 105. Accordingly, the barrier capping layer 130 may prevent a charge loss path from being formed in the upper portion of the device isolation layer 105.

On the other hand, the barrier capping layer 130 may lessen an electric field applied to the edge of the active region, thereby improving the retention characteristic of the device. The barrier capping layer 130 decreases the back tunneling, thereby improving the reliability of the device.

The nonvolatile memory device according to the above-described embodiments may be realized in various types of semiconductor packages. For example, the nonvolatile memory device according to the embodiment of the inventive concept may be packaged in such ways as package on package (PoP), ball grid array (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline (SOIC), shrink small-outline package (SSOP), thin small-outline (TSOP), thin quad flat pack (TQFP), system in package (SIP), multi chip package (MCP), wafer-level fabricated package (WFP), or wafer-level processed stack package (WSP). A package mounted with the nonvolatile memory device according to the embodiments of the inventive concept may further include a controller and/or a logic device, for example, controlling the semiconductor memory device.

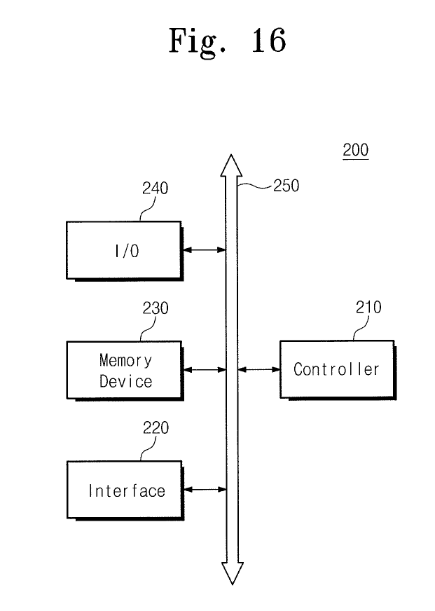

FIG. 16 is a block diagram illustrating an electronic system including the nonvolatile memory device according to embodiments of the inventive concept.

Referring to FIG. 16, an electronic system 200 according to the embodiment of the inventive concept may include a controller 210, an input/output device (I/O) 240, a memory device 230, an interface 220, and a bus 250. The controller 210, the input/output device (I/O) 240, the memory device 230, and/or the interface 220 may be connected to each other through the bus 250. The bus 250 corresponds to a transfer path of data.

The controller 210 includes at least one of a microprocessor, a digital signal processor, a microcontroller, and logic devices executing similar functions. The I/O device 240 may include a key pad, a keyboard, or a display device. The memory device 230 may store data and/or commands, and the like. The memory device 230 may include at least one of the nonvolatile memory devices disclosed in the above-described embodiments of the inventive concept. The memory device 230 may further include another type of semiconductor memory device (for example, a phase change memory device, a magnetic memory device, a DRAM device, and/or an SRAM device). The interface 220 executes a function of transmitting data to a communication network or receiving data from a communication network. The interface 220 may be realized in a wireless or wired form. For example, the interface 220 may include an antenna or a wireless/wired transceiver. Even though not illustrated, the electronic system 200 may further include a high-speed DRAM and/or a high-speed SRAM as an operational memory for improving the operation of the controller 210.

The electronic system 200 is applicable to a personal digital assistant (PDA), a portable computer, a web tablet, a wireless phone, a mobile phone, a digital music player, a memory card, or any electronic device capable of transmitting and/or receiving information in a wireless environment.

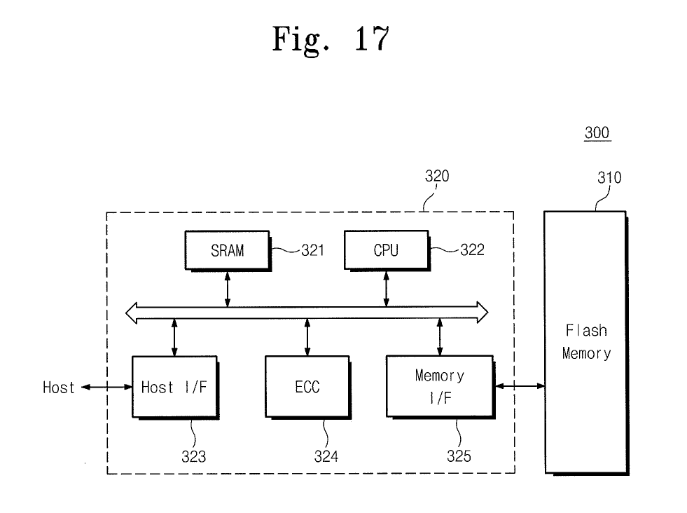

FIG. 17 is a block diagram illustrating a memory card including the nonvolatile memory device according to an embodiment of the inventive concept.

Referring to FIG. 17, a memory card 300 according to an embodiment of the inventive concept includes a memory device 310. The memory device 310 may include at least one of the nonvolatile memory devices disclosed in the above-described embodiments. The memory device 310 may further include another type of semiconductor memory device (for example, a phase change memory device, a magnetic memory device, a DRAM device, and/or an SRAM device). The memory card 300 may include a memory controller 320 controlling data exchange between a host and the memory device 310.

The memory controller 320 may include a processing unit 322 generally controlling the memory card. The memory controller 320 may include an SRAM 321 used as an operational memory of the processing unit 322. The memory controller 320 may further include a host interface 323 and a memory interface 325. The host interface 323 may have a protocol for exchanging data between the memory card 300 and a host. The memory interface 325 may connect the memory controller 320 to the memory device 310. The memory controller 320 may further include an error correction coding block (Ecc) 324. The error correction coding block 324 may detect and correct an error of data read from the memory device 310. Even though not illustrated, the memory card 300 may further include a ROM device storing code data used to interface a host. The memory card 300 may be used as a portable data storing card. Alternatively, the memory card 300 may be realized as a solid state disk (SSD) replacing a hard disk drive of a computer system.

According to the embodiments of the inventive concept, the nonvolatile memory device includes the barrier capping layer. The barrier capping layer may prevent the material forming the blocking insulating layer and the gate electrode from being spread into the upper portion of the device isolation layer. Therefore, the barrier capping layer may prevent the charge loss path from being formed on the upper portion of the device isolation layer.

Moreover, the barrier capping layer lessens the electric field applied to the edge of the active region, thereby improving the retention characteristic of the device. Furthermore, the barrier capping layer decreases the back tunneling, thereby improving the reliability of the device.

The above-disclosed subject matter is to be considered illustrative and not restrictive, and the appended claims are intended to cover all such modifications, enhancements, and other embodiments, which fall within the true spirit and scope of the inventive concept is to be determined by the broadest permissible interpretation of the following claims and their equivalents, and shall not be restricted or limited by the foregoing detailed description.

1. A nonvolatile memory device comprising:
a semiconductor substrate including a device isolation layer defining an active region;
a tunnel insulating layer on the active region;
a charge trapping layer on the tunnel insulating layer;
a blocking insulating layer on the charge trapping layer and the device isolation layer;
a gate electrode on the blocking insulating layer; and
a barrier capping layer between the device isolation layer and the blocking insulating layer.

2. The nonvolatile memory device of claim 1, wherein the barrier capping layer covers the device isolation layer and the charge trapping layer.

3. The nonvolatile device of claim 1, wherein the barrier capping layer comprises the same material as that of the charge trapping layer.

4. The nonvolatile device of claim 1, wherein the barrier capping layer covers the device isolation layer, and the blocking insulating layer is in contact with the charge trapping layer.

5. The nonvolatile device of claim 4, wherein the barrier capping layer includes a silicon oxynitride layer.

6. The nonvolatile device of claim 1, wherein a thickness of the barrier capping layer is thinner than that of the charge trapping layer.

7. The nonvolatile device of claim 1, wherein the blocking insulating layer includes a barrier insulating layer on the barrier capping layer and a high-k layer on the barrier insulating layer, and
the barrier insulating layer comprises the same material of that of the device isolation layer.

8-10. (canceled)
